(19) United States
(12) Patent Application Publication
(10) Pub. No.: US 2024/0186730 A1
(43) Pub. Date: Jun. 6, 2024

(54) Electrical Connector, Connecting Body Between a Circuit Board and Electrical Connector

(71) Applicant: Tyco Electronics Japan G.K., Kawasaki-shi (JP)

(72) Inventors: Masaaki Iwasaki, Kawasaki-shi (JP); Junya Tsuji, Kawasaki (JP)

(73) Assignee: Tyco Electronics Japan G.K., Kawasaki-shi (JP)

(21) Appl. No.: 18/524,984

(22) Filed: Nov. 30, 2023

(30) Foreign Application Priority Data
Dec. 2, 2022 (JP) 2022-193201

(51) Int. Cl. H01R 12/57; H01R 12/70; H01R 13/6471

(52) U.S. Cl. CPC H01R 12/57; H01R 12/7064; H01R 13/6471

(57) ABSTRACT

An electrical connector comprises a plurality of signal contacts, a plurality of ground contacts, a wafer, a first organizer, and a second organizer. The wafer supports the plurality of signal contacts and the plurality of ground contacts. The first organizer is attached to the wafer and positions the plurality of signal contacts. The second organizer is attached to the wafer, with the first organizer and the second organizer stacked on each other. The second organizer is in electrical contact with and positions the plurality of ground contacts.

### CROSS-REFERENCE TO RELATED APPLICATION

This application claims the benefit of Japanese Patent Application No. 2022-193201 filed on Dec. 2, 2022, the whole disclosure of which is incorporated herein by reference.

### FIELD OF THE INVENTION

The present invention relates to an electrical connector connected to a circuit board.

### BACKGROUND

In a server, or a router in a connection system used for the purpose of data communication at a data center or the like, two circuit boards may need to be connected together at an angle of 90° relative to each other. In this case, a male connector and a female connector are connected to the two circuit boards, respectively, and the male connector and the female connector are connected together, thereby connecting the two circuit boards. Electrical connectors of this type are known, wherein signal contacts for transmitting signals and ground contacts for ground (GND) are densely arranged. The signal contacts and the ground contacts are configured, for example, as press-fit type contacts. Further, the electrical connectors are configured by stacking as many wafers supporting the signal contacts and the ground contacts as needed.

When an electrical connector including a high density of signal contacts and ground contacts (which may be collectively referred to as contacts and/or the like) and a circuit board are connected together, the contacts and/or the like need to be aligned with electrically continuous portions of the circuit board. If the contacts or the like are of a press-fit type, they need to be inserted into through-holes formed in the circuit board without misalignment. In prior art solutions, however, misalignment of these signal and ground contacts is common, which negatively affects the function of the connector(s).

### SUMMARY

According to an embodiment of the present disclosure, an electrical connector comprises a plurality of signal contacts, a plurality of ground contacts, a wafer, a first organizer, and a second organizer. The wafer supports the plurality of signal contacts and the plurality of ground contacts. The first organizer is attached to the wafer and positions the plurality of signal contacts. The second organizer is attached to the wafer, with the first organizer and the second organizer stacked on each other. The second organizer is in electrical contact with and positions the plurality of ground contacts.

### BRIEF DESCRIPTION OF THE DRAWINGS

The invention will now be described by way of example with reference to the accompanying Figures, of which:

FIG. 1 is a diagram showing overall views of an electrical connector according to an embodiment;

FIG. 2 is a diagram showing a relation between contacts and/or the like of the electrical connector and a circuit board according to the embodiment;

FIG. 3 is a diagram showing a process in which the contacts and/or the like of the electrical connector are connected to the circuit board according to the embodiment;

FIG. 4 is a diagram of a part of the circuit board according to the embodiment as seen in a plan view;

FIG. 5 is a diagram showing a second organizer as seen from a face opposite the circuit board according to the embodiment;

FIG. 6 is a diagram of the electrical connector according to the embodiment, showing wafers retaining signal contacts and ground contacts with a first organizer attached thereto;

FIG. 7(a) is an isometric view showing the first organizer alone, and FIG. 7(b) is a diagram showing the first organizer and the wafers positioned relative to each other;

FIG. 8 is an isometric view of the electrical connector according to the embodiment, showing the wafers retaining the signal contacts and the ground contacts with the second organizer attached thereto;

FIG. 9(a) is an isometric view showing the second organizer alone, and FIG. 9(b) is a diagram showing the second organizer and the wafers with the first organizer attached thereto positioned relative to each other;

FIGS. 10(a) and 10(b) are diagrams illustrating movement of signal terminals, with FIG. 10(a) being a diagram showing their position in a free state, and FIG. 10(b) being a diagram showing their position in press contact with signal electrode pads; and

FIGS. 11(a) and 11(b) show a first electrical connector, with FIG. 11(a) being a diagram as seen from a face opposite a circuit board, and FIG. 11(b) being a cross sectional view along an arrowed line 11b-11b in FIG. 11(a).

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

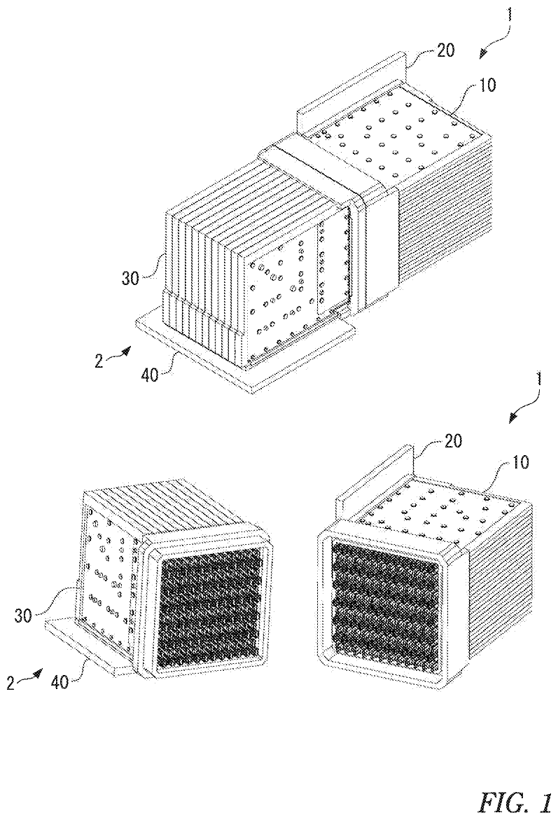

With reference to FIG. 1, a connector assembly according to an embodiment of the present disclosure includes a first connected assembly 1 of a first electrical connector 10 and a first circuit board 20, and a second connected assembly 2 of a second electrical connector 30 and a second circuit board 40. It should be noted that the first circuit board 20 and the second circuit board 40 shown in FIG. 1 are only partially shown to an extent that allows their respective connections to the first electrical connector 10 and the second electrical connector 30 to be recognized. In FIG. 1, the first electrical connector 10 and the second electrical connector 30 are mated with each other, thereby configuring DPO (direct plug orthogonal), by way of example, in which the first circuit board 20 and the second circuit board 40 are orthogonal in orientation to each other. In the DPO, electrical signals transmitted between the first circuit board 20 of the first connected assembly 1 and the second circuit board 40 of the second connected assembly 2 are exchanged between the first electrical connector 10 and the second electrical connector 30. The first electrical connector 10 according to the present embodiment includes two positioning members: a first organizer or positioning element 60 and a second organizer or positioning element 70 responsible for positioning a plurality of signal contacts 13 and a plurality of ground contacts 15, respectively.

In the illustrative configuration, an advantageous effect of the first connected assembly 1, specifically, the first electrical connector 10 and the first circuit board 20, will be described below. It should be noted that the second connected assembly 2 including the second electrical connector 30 and the second circuit board 40 has a configuration like the first connected assembly 1, and therefore descriptions of the second connected assembly 2 will be omitted by describing the first connected assembly 1.

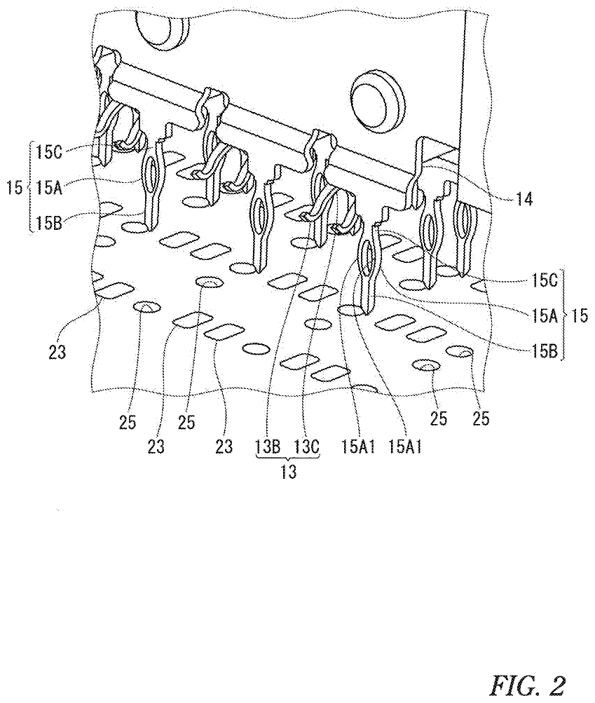

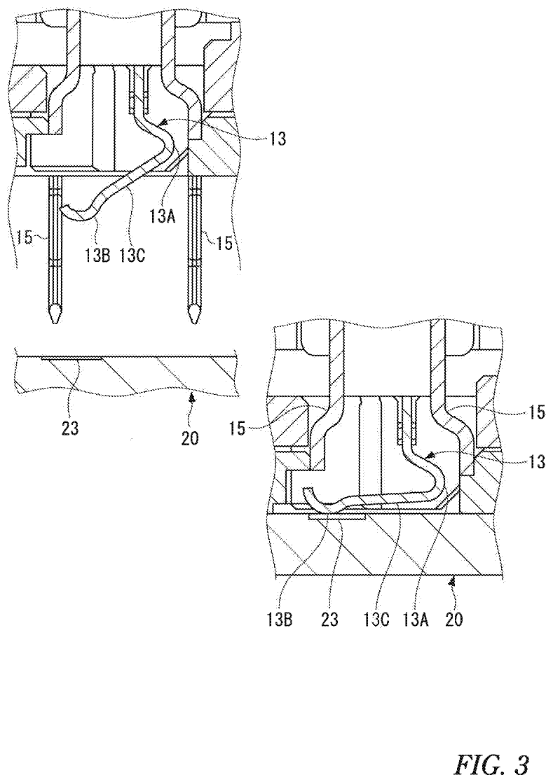

### <First Electrical Connector 10: See FIGS. 2, 3>

The first electrical connector 10 is realized by stacking a plurality of wafers 11 together. With regard to a general configuration example of the wafer 11, two wiring boards and two shield board are provided. The wiring boards and the shield boards have a generally rectangular shape as seen in a plan view.

The two wiring boards are board-shaped members in which metal wiring composed of a plurality of individual wires arranged is insert-molded in a resin board. A contact brought into contact with a contact of the second electrical connector 30 that is a mating connector is formed at one end of each of the individual wires constituting the metal wiring. In addition, the plurality of press-contact type signal contacts 13 each of which are brought into electrical contact with a corresponding one of a plurality of signal electrode pads 23 formed on the first circuit board 20 are arranged at the other end of each of these individual wires (see FIG. 2).

The two shield boards are so arranged as to hold the two wiring boards stacked on each other therebetween. A plurality of ground contacts connected to ground contacts of the second electrical connector 30 that is a mating counterpart are arranged on one side face of each of these two shield boards. In addition, the plurality of ground contacts 15 inserted into a plurality of through-hole electrodes 25 functioning as ground electrodes formed in the first circuit board 20 are arranged on another side face of these two shield boards 14 (see FIG. 2).

A press-contact type contact is used as the signal contact 13, by way of example. The signal contact 13, as shown in FIG. 3, includes a bent portion 13A plastically deformed in a U-shape, a contact portion 13B coming into contact with the signal electrode pad 23 of the first circuit board 20, and a beam portion 13C connecting the bent portion 13A and the contact portion 13B. A side having the contact portion 13B of the signal contact 13 is defined as a distal end. When the contact portion 13B is pressed against the signal electrode pad 23 in the process of assembling the first electrical connector 10 and the first circuit board 20 together, a distal end side relative to the bent portion 13A having high rigidity is elastically deformed, and the contact portion 13B is thereby brought into press contact with the signal electrode pad 23. The signal contact 13 can be formed, for example by stamping and forming a sheet material composed of a copper alloy having excellent electrical conductivity and elasticity. The same applies to the ground contact 15.

A press-fit type contact is used as the ground contact 15 by way of example. The ground contact 15 is also referred to as a needle-eye type, and includes of a press-fit portion 15A, a guide portion 15B continuous with one end of the press-fit portion 15A, and a base portion 15C continuous with the other end of the press-fit portion 15A, as shown in FIG. 2. The press-fit portion 15A includes a pair of elastic press-contact pieces 15A1, 15A1, and an airgap 15A2 between the elastic press-contact pieces 15A1, 15A1. The elastic press-contact pieces 15A1, 15A1 each have a clamped-clamped beam structure, and are so formed as to curve outward like an arc with the airgap 15A2 therebetween. Therefore, the elastic press-contact pieces 15A1, 15A1 can elastically deform by deflecting inward or outward with the airgap 15A2 therebetween. Therefore, when the ground contact 15 is inserted into the through-hole electrode 25, the elastic press-contact pieces 15A1, 15A1 are elastically deformed inward using the airgap 15A2 as a deflection airgap, and a reaction force of the elastic deformation causes respective outer peripheral faces of the elastic press-contact pieces 15A1, 15A1 to be pressed against the through-hole electrode 25.

### <First Circuit Board 20: See FIGS. 2, 3, 4>

The first circuit board 20 includes a board main body 21 having a front face 21A and a back face 21B, the plurality of signal electrode pads 23 formed on the front face 21A of the board main body 21, and the plurality of through-hole electrodes 25 formed through the front face 21A and the back face 21B of the board main body 21. The board main body 21 is realized by stacking a plurality of sheets of board materials together. Signal paths that are connected to the plurality of signal electrode pads 23 formed on the front face 21A are formed in the board materials.

The signal electrode pad 23 is brought into press contact with the signal contact 13 of the first electrical connector 10 assembled to the first circuit board 20, and an electrical signal is thereby transmitted between the first electrical connector 10 and the first circuit board 20. It should be noted that, in FIGS. 2 to 4, though the signal electrode pads 23 are shown on the front face 21A of the board main body 21, the signal paths each of which is electrically connected to a corresponding one of the plurality of signal electrode pads 23 and is involved in transmission of an electrical signal are formed inside the board main body 21 along a planar direction of the board main body 21. The signal paths are so formed so as to avoid the through-hole electrodes 25.

It should be noted that, though an example is shown here in which the signal electrode pad 23 is used to make electrical connection to the press-contact type signal contact 13, the signal contact 13 may be of a press-fit type, like the ground contact 15, and this press-fit type signal contact 13 may be inserted into a through-hole electrode formed in the first circuit board 20. The signal electrode pad 23, however, is advantageous in terms of ensuring mechanical strength of the board main body 21 because no through-hole needs to be formed in the board main body 21, and in addition, even if the signal electrode pad 23 is formed on the front face 21A, the signal paths can be formed inside the board main body 21.

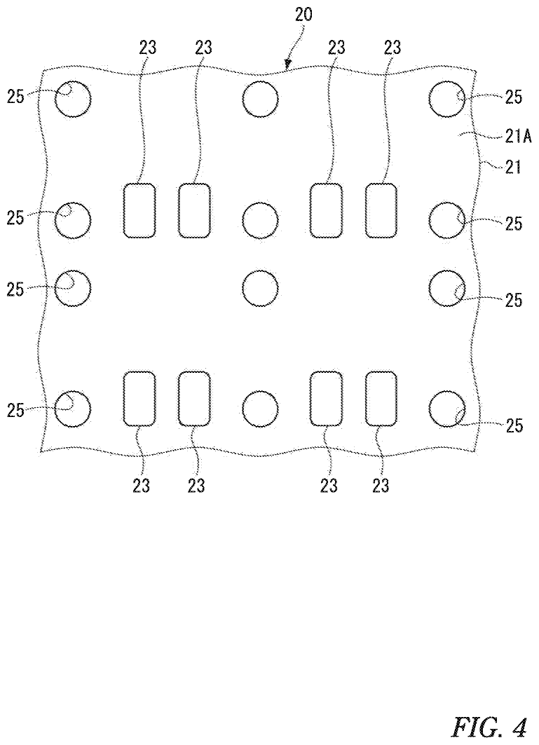

The through-hole electrode 25, as shown in FIG. 4, is composed of a through-hole TH formed in the board main body 21, and an electrically conductive film CP formed, for example by plating, on a thickness-wise wall face of the board main body 21 enclosing the through-hole TH. The electrically conductive film CP is typically also formed around an opening of the through-hole electrode 25 on the front face 21A and the back face 21B. Plating, such as a gold plating or a silver plating, is used as a plating constituting the electrically conductive film CP. In addition, the electrically conductive film CP is not limited to a plating, and an electrically conductive film CP formed by another means, for example, vapor deposition, sputtering, or the like, may be used. The signal electrode pad 23 is formed of the same or similar electrically conductive film.

When the ground contact 15 is inserted into the through-hole electrode 25, the elastic press-contact pieces 15A1, 15A1 of the press-fit portion 15A are elastically deformed toward the airgap inside. The reaction force thereof causes the respective outer peripheral faces of the elastic press-contact pieces 15A1, 15A1 to be pressed against the electrically conductive film CP of the through-hole electrode 25. The ground (GND) is thereby achieved between the first electrical connector 10 and the first circuit board 20.

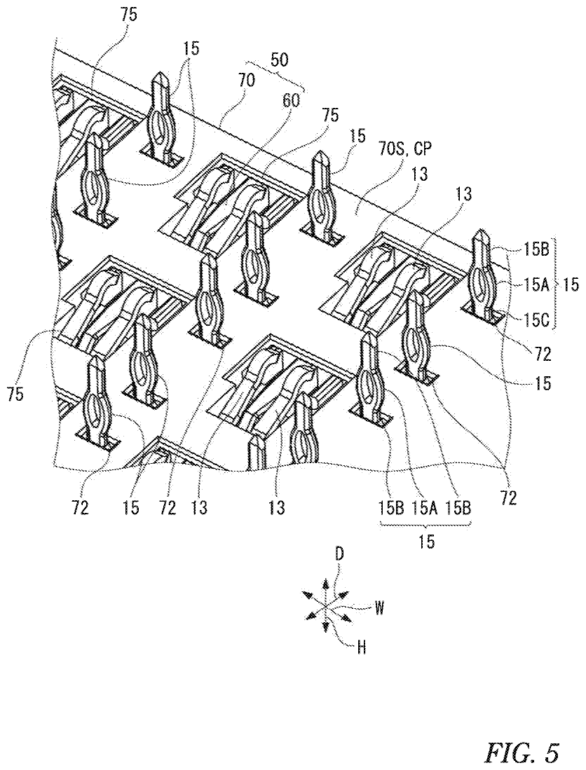

### <Organizer 50: See FIG. 5>

The first electrical connector 10 includes an organizer 50 responsible for positioning the signal contact 13 and the ground contact 15. The organizer 50, as shown in FIG. 5, includes the first organizer 60 positioning the signal contact 13, and the second organizer 70 positioning the ground contact 15. In other words, the organizer 50 allocates a positioning function for the signal contact 13 and a positioning function for the ground contact 15 to the first organizer 60 and the second organizer 70, respectively. The first organizer 60 and the second organizer 70 are formed separately, but they are attached, in a state of being stacked on each other, to the wafer 11 constituting the first electrical connector 10. The first organizer 60 and the second organizer 70 will be described below in this order.

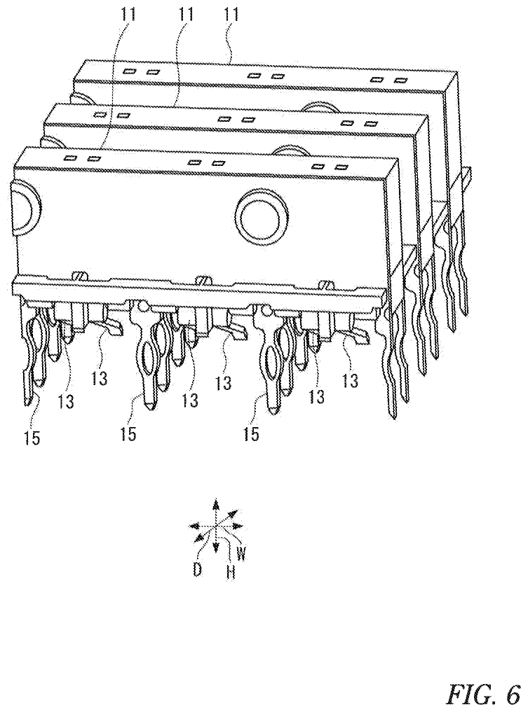

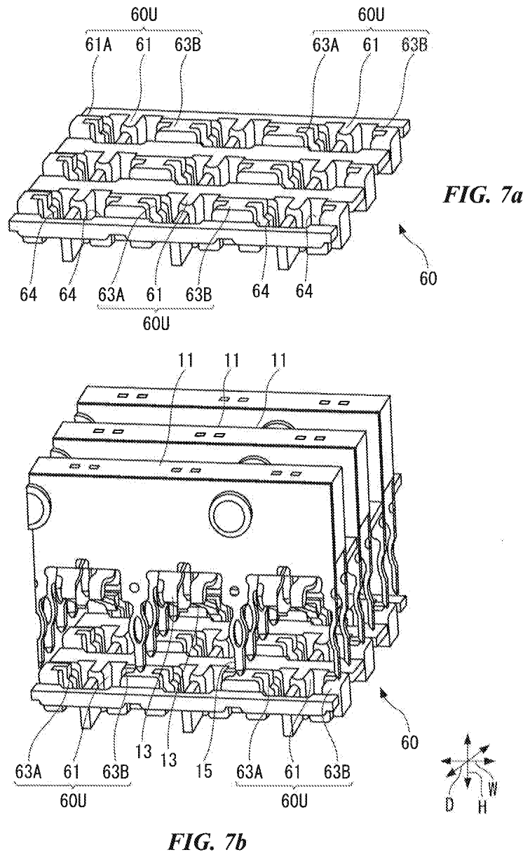

### <First Organizer 60: See FIGS. 6, 7>

The first organizer 60, as shown in FIG. 6, is attached to the plurality of wafers 11, thereby positioning the signal contact 13. It should be noted that the wafer 11 is shown in FIGS. 6 to 8 only to an extent required for illustrating attachment of the first organizer 60 and the second organizer 70. The first organizer 60 is integrally formed by injection-molding a resin material that is an electrically insulating material, by way of example. The first organizer 60 positions a pair of adjacent signal contacts 13, 13 as a unit. If this is referred to as a positioning unit 60U, the first organizer 60 includes the positioning units 60U corresponding in number to the pairs of signal contacts 13, 13. In the first organizer 60, the plurality of positioning units 60U are arranged side by side in a width direction W and a depth direction D. It should be noted that, for illustrative convenience, the width direction W, the depth direction D, and a height direction H are defined as shown in FIG. 5 and the like. The positioning unit 60U is an example of a first support portion of the present invention.

The positioning unit 60U, as shown in FIG. 7(a), includes a central guide 61 provided between the pair of signal contacts 13, 13 when the first organizer 60 is attached to the plurality of wafers 11, and lateral guides 63A, 63B provided with the central guide 61 therebetween and each spaced from the central guide 61. The central guide 61 and the lateral guides 63A, 63B are arranged side by side in the width direction W in order of the lateral guide 63A, the central guide 61, and the lateral guide 63B. An airgap passing through the first organizer 60 in the height direction H is located between the central guide 61 and the lateral guide 63A and between the central guide 61 and the lateral guide 63B, and these two airgaps in the positioning unit 60U constitute accommodation spaces 64, 64 for the pair of signal contacts 13, 13, respectively. The accommodation spaces 64, 64 are so dimensioned in the width direction W and the depth direction D as to prevent each of the pair of signal contacts 13, 13 accommodated therein from being misaligned in the width direction W and the depth direction D. Whether or not they are misaligned here is determined based on whether or not the contact portion 13B of the signal contact 13 is in press contact with the corresponding signal electrode pad 23 in a predetermined position, at least either when the first electrical connector 10 and the first circuit board 20 are connected together or after they are connected to form a connected assembly. The plurality of wafers 11 (the first electrical connector 10) and the first organizer 60, as shown in FIG. 7(b), are aligned with each other, and thereafter attached to each other in such a manner that the pair of signal contacts 13, 13 are accommodated in the accommodation spaces 64, 64, as shown in FIG. 6. After the first organizer 60 is attached to the wafer 11, then the second organizer 70 is attached.

### <Second Organizer 70: See FIGS. 5, 8, 9>

The second organizer 70 is attached to the plurality of wafers 11 to which the first organizer 60 has been attached, thereby positioning the ground contact 15. In addition, the second organizer 70 functions as ground (GND) between the second organizer 70 and the ground contact 15, and they are at the same electrical potential. The second organizer 70 is integrally formed by injection-molding a resin material that is an electrically insulating material, by way of example. The second organizer 70, however, as shown in FIG. 5, has an electrically conductive film CP formed, for example by plating, on a face 70S opposite the first circuit board 20 so as to function as ground.

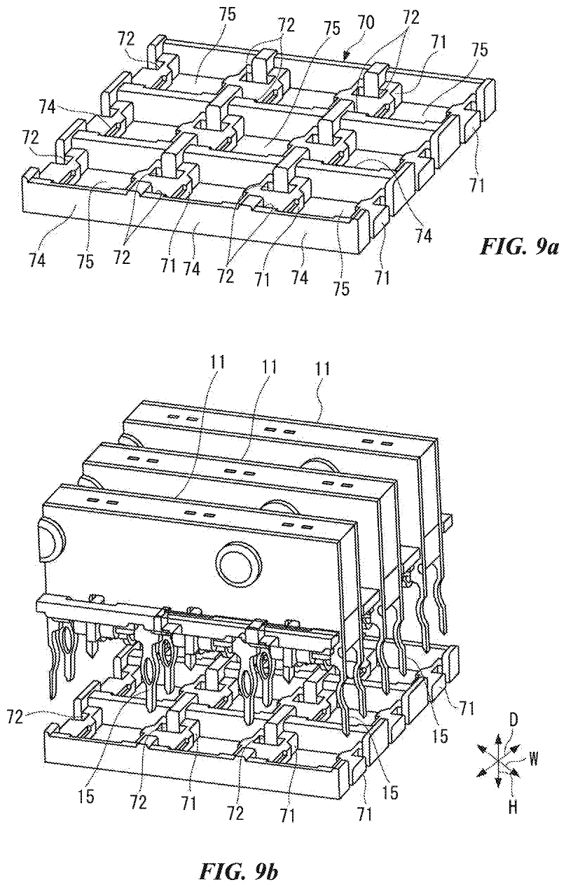

In the second organizer 70, as shown in FIGS. 5 and 9, a plurality of arrangement spaces 75 in which the positioning units 60U of the first organizer 60 stacked on the second organizer 70 are arranged in a grid or matrix in the width direction W and in the depth direction D. The arrangement spaces 75 are separated by a positioning block 71 in the width direction W, and separated by a partition panel 74 in the depth direction D. The positioning block 71 is an example of a second support portion of the present invention.

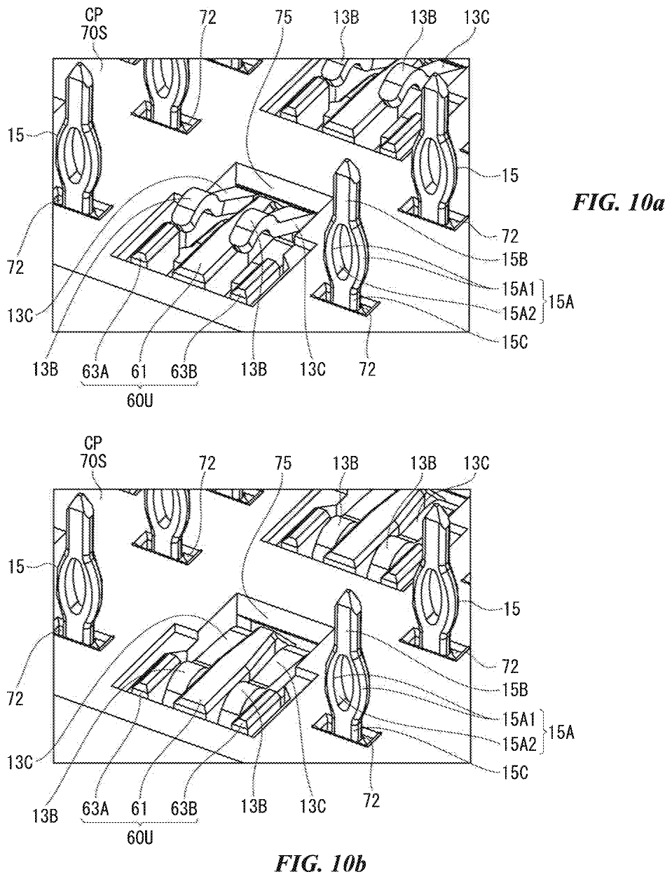

Each of the positioning blocks 71 has two insertion holes each having a rectangular opening which passes through the front and back of the second organizer 70 and into which the ground contact 15 is inserted. The two insertion holes 72 are provided at a distance from each other in the depth direction D. Therefore, as a whole, the plurality of insertion holes 72 are arranged side by side in the depth direction D and the width direction W. In addition, as shown in FIG. 10, a press-fit support portion 76 into which the base portion 15C of the ground contact 15 is press-fitted is provided deeper than the insertion hole 72. When the base portion 15C is press-fitted into the press-fit support portion 76, the press-fit support portion 76 mechanically restrains the base portion 15C, thereby positioning the ground contact 15.

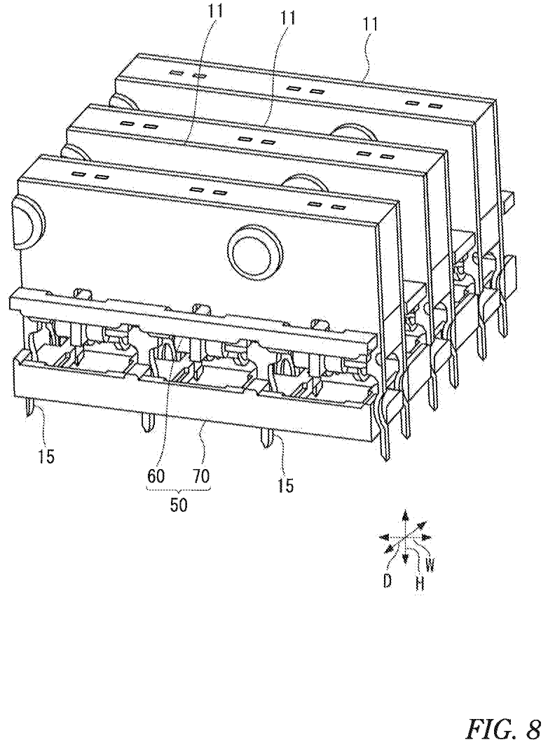

As shown in FIG. 9(b), after the plurality of wafers 11 with the first organizer 60 attached thereto and the second organizer 70 are aligned with each other, they are assembled together while each ground contact 15 is being inserted into the corresponding insertion hole 72. Thereby, as shown in FIG. 8, the first connected assembly 1 is made.

### <Stacked Structure of the First Organizer 60 and the Second Organizer 70: See FIGS. 8, 10, 11>

The first organizer 60 and the second organizer 70, as shown in FIG. 8, are assembled to an electrical connector intermediate composed of the plurality of wafers 11 in order of the first organizer 60 and the second organizer 70. Therefore, the first organizer 60 and the second organizer 70 are stacked on the electrical connector intermediate in order of the first organizer 60 and the second organizer 70. This stack, however, does not mean that the first organizer 60 and the second organizer 70 are entirely in direct contact with each other in their planer direction. Some portions of the first organizer 60 and the second organizer 70 are in direct contact with each other in the height direction H, and other portions thereof are spaced from each other in the height direction H. In particular, the positioning unit 60U of the first organizer 60 is arranged in the arrangement space 75 of the second organizer 70, and the contact portion 13B of the signal contact 13 positioned by the positioning unit 60U is thereby exposed via the arrangement space 75. This structure enables the contact portion 13B to be brought into press contact with the signal electrode pad 23 of the first circuit board 20.

In the electrical connector intermediate with the first and second organizers 60, 70 assembled thereto, the signal contact 13 before press contact with the signal electrode pad 23 projects outside from the arrangement space 75, as shown in FIG. 10(a). When the electrical connector intermediate is assembled to the first circuit board 20, however, the contact portion 13B is brought into press contact with the signal electrode pad 23, and then the signal contacts 13, 13 enter the accommodation spaces 64, 64 between the central guide 61 and the lateral guides 63A, 63B of the first organizer 60 (the positioning unit 60U), as shown in FIG. 10(b). Thereby, one of the signal contacts 13 is held between the central guide 61 and the lateral guide 63A and thereby positioned in the width direction W, and the other signal contact 13 is held between the central guide 61 and the lateral guide 63B and thereby positioned in the width direction W. The signal contact 13 positioned may be brought into contact with the central guide 61 and the lateral guides 63A, 63B and be thereby positioned, but a small gap may be provided between the signal contact 13 and the central guide 61 and between the signal contact 13 and the lateral guides 63A, 63B. In the latter case, the signal contact 13 may be displaced in the width direction W, but the first organizer 60 can fulfill a positioning function as long as the distance of the displacement is small.

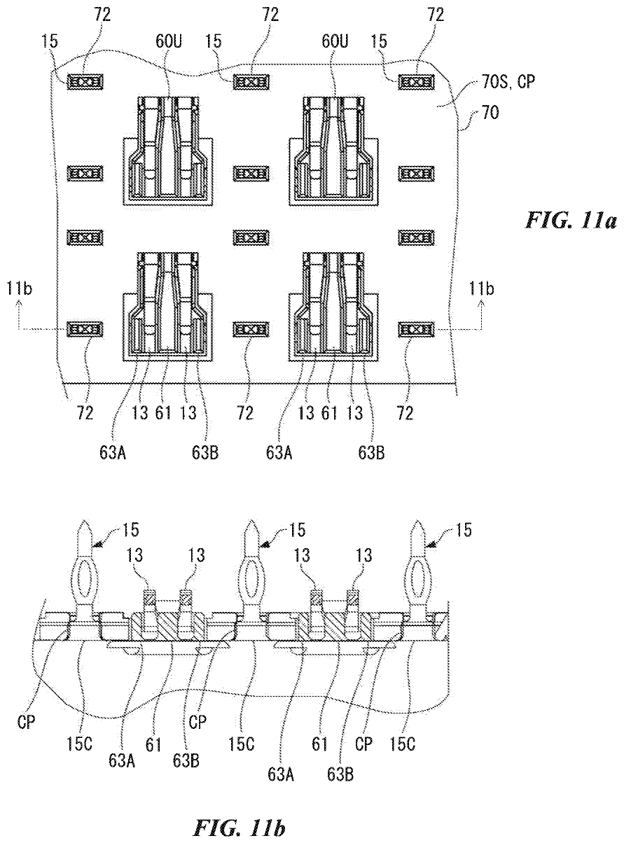

Next, the ground contact 15, as shown in FIG. 11, passes through the insertion hole 72 of the second organizer 70, and projects from the face 70S opposite of the second organizer 70. The ground contact 15 has the base portion 15C supported by the press-fit support portion 76 of the second organizer 70. An electrically conductive film CP continuous from the face 70S opposite is formed on the surface of the press-fit support portion 76, and the ground contact 15 is electrically connected to the electrically conductive film CP via the base portion 15C.

### <Advantageous Effects Produced by the First Electrical Connector 10>

The first electrical connector 10 described above produces the following advantageous effects. The first electrical connector 10 includes the first organizer 60 and the second organizer 70, the first organizer 60 positions the signal contact 13, and the second organizer 70 positions the ground contact 15. Here, in order to ensure high ground performance, the electrically conductive film CP is formed on the face 70S opposite of the second organizer 70. Therefore, if the second organizer 70 alone has a positioning function for the signal contact 13 in addition to a positioning function for the ground contact 15, the signal contact 13 may come into contact with the electrically conductive film CP. This makes it difficult for an organizer having an electrically conductive film CP formed thereon to have a positioning function for the signal contact 13, and, in that case, the signal contact 13 is not positioned when the first electrical connector 10 is assembled with the first circuit board 20. On the other hand, if the first organizer 60 alone has a positioning function for the ground contact 15 in addition to a positioning function for the signal contact 13, high ground performance cannot be ensured since the electrically conductive film CP is not formed.

Therefore, according the first electrical connector 10 including the first organizer 60 and the second organizer 70, the signal contact 13 and the ground contact 15 can be reliably individually positioned, and reliable signal transmission by the signal contact 13 and high ground performance by the ground contact 15 can also be ensured.

In addition to the above, selective adoption/removal of a configuration mentioned in the above embodiment, or appropriate modification thereof to another configuration may be made without departing from the spirit of the present invention.

The subject matter of the present invention may be the first connected assembly 1 of the first electrical connector 10 and the first circuit board 20 alone. In other words, a mating counterpart for the first electrical connector 10 is not limited to the second electrical connector 30 assembled with the second circuit board 40, and a mating counterpart for the first electrical connector 10 may be an electrical connector not connected to a circuit board.

A press-contact type contact has been illustrated as the signal contact 13, but the present invention is not limited thereto, and a press-fit type contact like the ground contact 15 may be used.

The first organizer 60 and the second organizer 70 stacked on the wafer 11 in order of the first organizer 60 and the second organizer 70 have been shown by way of example, but the present invention is not limited thereto, and they may be stacked on the wafer 11 in order of the second organizer 70 and the first organizer 60. As shown in the present embodiment, however, if they are stacked in order of the first organizer 60 and the second organizer 70, the electrically conductive film CP of the second organizer 70 is arranged in proximity to the first circuit board 20. This is advantageous in terms of ground performance if a ground face is located on a face opposite the second organizer 70 of the first circuit board 20. On the other hand, if they are stacked in order of the second organizer 70 and the first organizer 60, the first organizer 60 composed entirely of an insulating material is arranged in proximity to the first circuit board 20. Then, a signal pattern formation region can be increased on a face opposite the first organizer 60 of the first circuit board 20.

In addition, the integral first organizer 60 and the integral second organizer 70 for the plurality of wafers 11 have been shown by way of example, but the present invention is not limited thereto, and a first organizer and a second organizer may be attached to each of the plurality of wafers 11. In other words, the present invention allows a single first organizer and a single second organizer to be attached to each single wafer 11. The integral first organizer 60 and the integral second organizer 70 for the plurality of wafers 11 are advantageous in terms of cost. On the other hand, a single first organizer and a single second organizer for each single wafer 11 can achieve a more preferred form to fulfill their function as an organizer.

The second organizer 70 composed of a composite body in which the electrically conductive film CP is formed on the face 70S opposite of the molded body composed of a resin material has been shown by way of example, but the present invention allows the second organizer 70 to be composed entirely of an electrically conductive material. In this case, the second organizer 70 can be obtained by injection molding of an electrically conductive resin material, or the second organizer 70 may be obtained by metal injection molding of an electrically conductive metal powder. The electrically conductive resin material does not mean that the resin material itself has electrical conductivity, but can be obtained by dispersing powders, fibers, or the like having electrical conductivity in the resin material.

In addition, those areas in which it is believed that those of ordinary skill in the art are familiar, have not been described herein in order not to unnecessarily obscure the invention described. Accordingly, it has to be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. An electrical connector, comprising:
a plurality of signal contacts;
a plurality of ground contacts;
a wafer supporting the plurality of signal contacts and the plurality of ground contacts;
a first organizer attached to the wafer and positioning the plurality of signal contacts; and
a second organizer attached to the wafer, the second organizer in electrical contact with and positioning the plurality of ground contacts.

2. The electrical connector according to claim 1, wherein the first organizer and the second organizer are stacked on each other.

3. The electrical connector according to claim 2, wherein:
the electrical connector is connected to a circuit board;
the first organizer comprises an electrically insulating material; and
the second organizer comprises an electrically conductive material.

4. The electrical connector according to claim 3, wherein the second organizer defines a first face opposite the circuit board formed of the electrically conductive material, the plurality of ground contacts in electrical contact with the electrically conductive material.

5. The electrical connector according to claim 3, wherein the second organizer includes:
an electrically conductive film formed on the first face; and
a molded body supporting the electrically conductive film and comprising an electrically insulating material.

6. The electrical connector according to claim 1, wherein the first organizer includes a plurality of first support portions spaced from each other and supporting the plurality of signal contacts.

7. The electrical connector according to claim 6, wherein the second organizer includes a plurality of second support portions supporting the plurality of ground contacts.

8. The electrical connector according to claim 7, wherein a plurality of arrangement spaces pass through a front and a back of the second organizer, the plurality of second support portions and the plurality of arrangement spaces being alternated in a planar direction.

9. The electrical connector according to claim 8, wherein the first support portion of the first organizer is arranged in the arrangement space of the second organizer.

10. The electrical connector according to claim 1, wherein:
each of the plurality of signal contacts is a press-contact type contact; and
each of the plurality of ground contacts is a press-fit type contact.

11. A connector assembly, comprising:
an electrical connector, including:
a signal contact;
a ground contact;
a wafer supporting the signal contact and the ground contact;
a first organizer attached to the wafer and positioning the signal contact; and
a second organizer attached to the wafer, the second organizer in electrical contact with and positioning the ground contact; and
a circuit board, including a signal electrode and a ground electrode, the signal contact of the electrical connector electrically connected to the signal electrode of the circuit board, and the ground contact of the electrical connector is electrically connected to the ground electrode of the circuit board.

12. The connector assembly according to claim 11, wherein:
the circuit board further includes:
a plurality of pad type signal electrodes; and
a plurality of ground electrodes formed around a through-hole passing through a front and a back of the circuit board; and
the signal contact and the ground contact include a plurality of signal contacts and a plurality of ground contacts, respectively.

13. The connector assembly according to claim 12, wherein the plurality of signal contacts are in press contact with the signal electrodes, and the plurality of ground contacts are press-fitted in the ground electrodes.

14. An electrical connector, comprising:
a wafer adapted to support a plurality of signal contacts and a plurality of ground contacts;
a first organizer attached to the wafer and adapted to receive and locate the plurality of signal contacts; and
a second organizer attached to the wafer and in electrical contact with the plurality of ground contacts, and responsible for positioning the ground contacts.

15. The electrical connector according to claim 14, wherein:
the electrical connector is adapted to be connected to a circuit board;
the first organizer comprises an electrically insulating material; and
the second organizer defines a first face adapted to be positioned opposite the circuit board and comprising an electrically conductive material in electrical contact with the plurality of ground contacts.

16. The electrical connector according to claim 15, wherein the second organizer further includes an electrically conductive film formed on the first face opposite.

17. The electrical connector according to claim 16, wherein the second organizer further includes a molded body supporting the electrically conductive film and comprising an electrically insulating material.

18. The electrical connector according to claim 14, wherein:
the first organizer includes a plurality of first support portions supporting the plurality of signal contacts, the plurality of first support portions being spaced from each other; and
the second organizer includes a plurality of second support portions supporting the plurality of ground contacts, and a plurality of arrangement spaces passing through a front and a back of the second organizer, the plurality of second support portions and the plurality of arrangement spaces being alternated in a planar direction.

19. The electrical connector according to claim 18, wherein the plurality of first support portions of the first organizer are arranged in the plurality of arrangement spaces of the second organizer.

20. The electrical connector according to claim 14, wherein:
each of the plurality of signal contacts is a press-contact type contact; and
each of the plurality of ground contacts is a press-fit type contact.
